(19) United States
(12) Patent Application Publication
(10) Pub. No.: US 2015/0147487 A1
(43) Pub. Date: May 28, 2015

(54) METHOD AND APPARATUS FOR FORMING ORGANIC MONOLAYER

(71) Applicant: TOKYO ELECTRON LIMITED, Tokyo (JP)

(72) Inventors: Takashi FUSE, Yamanashi (JP); Tomohito MATUO, Yamanashi (JP); Hidetoshi KINOSHITA, Yamanashi (JP)

(21) Appl. No.: 14/553,914

(22) Filed: Nov. 25, 2014

(30) Foreign Application Priority Data
Nov. 26, 2013 (JP) 2013-244184

(51) Int. Cl. B05D 1/00; C23C 16/52; C23C 16/50; C23C 16/452

(52) U.S. Cl. CPC B05D 1/60; B05D 1/62; C23C 16/452; C23C 16/52; C23C 16/50
USPC 427/569; 427/255.26; 427/255.27; 118/704

(57) ABSTRACT

A method for forming an organic monolayer includes supplying to an object an organic material gas including organic molecules, each molecule having a binding site that is to be chemically bonded to a surface of the object. The method further includes supplying excited hydrogen to the organic material gas before the organic material gas reaches the object to substitute an end of the binding site with hydrogen, and forming an organic monolayer by reaction between the end substituted with the hydrogen and the object.

### CROSS-REFERENCE TO RELATED APPLICATIONS

This application claims priority to Japanese Patent Application No. 2013-244184 filed on Nov. 26, 2013, the entire contents of which are incorporated herein by reference.

### FIELD OF THE INVENTION

The present invention relates to a method and an apparatus for forming an organic monolayer represented by a self-assembled monolayer.

### BACKGROUND OF THE INVENTION

Recently, an organic thin film made of an organic compound is used in various fields. For example, there is an organic semiconductor film used for an organic semiconductor such as an organic transistor.

As for the organic thin film made of the organic compound, there is known a self-assembled monolayer (SAM) that is an organic monomolecular film having self-assembled molecular arrangement.

The self-assembled monolayer is obtained using organic molecules each having as an end group a functional group that can form predetermined chemical bonding with a predetermined substrate. The organic molecules form chemical bondings to a surface of the substrate, and anchored organic molecules are regularly arranged by the bondage from the surface of the substrate and interaction between the organic molecules themselves, thereby forming a monolayer.

The self-assembled monolayer effectively used as an organic semiconductor film is also effective in modifying a surface of a substance. For example, the self-assembled monolayer is used to improve electrical characteristics of an organic transistor by modifying a substrate surface of the organic transistor (controlling wetting property and lipophilic property). Japanese Patent Application Publication No. 2005-86147 discloses a method of modifying a surface of a substrate by forming a self-assembled monolayer using a silane coupling agent on the substrate. The self-assembled monolayer using the silane coupling agent has as an organic functional group an alkyl group or a fluoroalkyl group and can be used to modify the surface of the substrate to be water-repellent.

In Japanese Patent Application Publication No. 2005-36147, it is also disclosed that the self-assembled monolayer using the silane coupling agent can be formed simply by exposing a substrate to vapor of the silane coupling agent, or dipping a substrate in a solution of the silane coupling agent, or coating a substrate with the silane coupling agent.

In the above method, a gas or a liquid for forming a self-assembled monolayer is adsorbed onto a surface of the substrate and then silane coupling reaction occurs. However, the above method is disadvantageous in that a long period of time is required to form a desired self-assembled monolayer because the silane coupling reaction proceeds at a considerably low speed. Therefore, problems such as a low throughput, cross contamination and the like occur. In addition, the above method is disadvantage in that the controllability in film formation is poor and a film formed on a substrate is easily peeled off because the film is difficult to be formed at a high density on the substrate.

### SUMMARY OF THE INVENTION

In view of the above, the present invention provides a method and an apparatus capable of forming an organic monolayer within a short period of time with good controllability.

In accordance with an aspect of the present invention, there is provided a method for forming an organic monolayer, including: supplying to an object an organic material gas including organic molecules, each molecule having a binding site that, is to be chemically bonded to a surface of the object; supplying excited hydrogen to the organic material gas before the organic material gas reaches the object to substitute an end of the binding site with hydrogen; and forming an organic monolayer by reaction between the end substituted with the hydrogen and the object.

In accordance with another aspect of the present invention, there is provided an apparatus for forming an organic monolayer on a surface of an object, the apparatus including: a chamber configured to accommodate the object;

an organic material gas supply unit configured to supply into the chamber an organic material gas including organic molecules, each molecule having a binding site that is to be chemically bonded to the surface of the object; an excited hydrogen generation mechanism configured to generate excited hydrogen in the chamber; and a gas exhaust unit configured to exhaust an inside of the chamber; and a control unit configured to supply the excited hydrogen from the excited hydrogen generation mechanism to the organic material gas supplied from the organic material gas supply unit before the organic material gas reaches the object in the chamber, so that an end of the binding site of each organic molecule is substituted with hydrogen and an organic monolayer is formed by reaction between the end substituted with the hydrogen and the object.

### BRIEF DESCRIPTION OF THE DRAWINGS

The objects and features of the present invention will become apparent from the following description of embodiments, given in conjunction with the accompanying drawings, in which:

FIG. 1 is a cross sectional view showing an example of an apparatus for implementing an organic monolayer forming method in accordance with an embodiment of the present invention;

FIG. 2 is a cross sectional view showing another example of the apparatus for implementing the organic monolayer forming method in accordance with the embodiment of the present invention; and

FIGS. 3A and 3B are views for explaining the organic monolayer forming method in accordance with the embodiment of the present invention.

### DETAILED DESCRIPTION OF THE EMBODIMENTS

(Organic Monolayer Forming Apparatus)

First, an example of an apparatus for implementing an organic monolayer forming method in accordance with an embodiment of the present invention will be described.

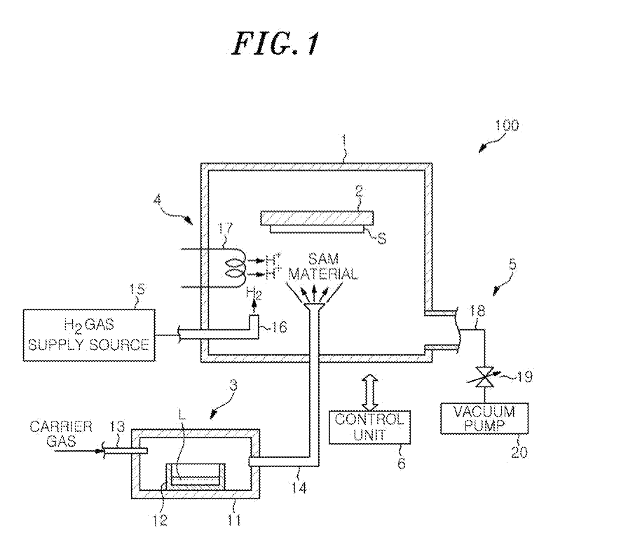

FIG. 1 is a cross sectional view showing an organic monolayer forming apparatus. As shown in FIG. 1, an organic monolayer forming apparatus 100 (hereinafter, simply referred to as “apparatus 100”) includes: a chamber 1 in which an organic molecular film is formed on a substrate S; a substrate holder 2 for holding a substrate in the chamber 1; an SAM material supply system 3 for supplying a self-assembled monolayer (SAM) material into the chamber 1; an excited hydrogen generation mechanism 4 for generating hydrogen in an excited state (hereinafter, referred to as “excited hydrogen”) in the chamber 1; a gas exhaust system 5 for exhausting the inside of the chamber 1; and a control unit 6.

The substrate holder 2 is provided at an upper portion within the chamber 1 and holds a substrate S such that a surface of the substrate S on which a film is formed faces downward. The substrate holder 2 may include a heating unit for heating the substrate S. In this case, a heating temperature of the substrate S is preferably 200° C. or less. When the heating is not performed, the substrate S is maintained at a room temperature. The SAM material supply system 3 includes: a gas generation container 11; a SAM material accommodating container 12 provided in the gas generation container 11; a carrier gas introduction line 13 for introducing a carrier gas into the gas generation container 11; and a SAM material gas supply line 14 for supplying a SAM material gas generated in the gas generation container 11 into the chamber 1. The SAM material gas supply line 14 has a leading end through which the SAM material gas is discharged toward the substrate S. The SAM material gas vaporized from a liquid SAM material L in the SAM material accommodating container 12 is transferred by the carrier gas and supplied into the chamber 1 through the SAM material gas supply line 14. When the vaporization is insufficient or the SAM material is in a solid state at a room temperature, a heater may be provided to the SAM material accommodating container 12.

The excited hydrogen generation mechanism 4 includes:

a hydrogen gas supply source 15 provided outside the chamber hydrogen gas supply line 16 for guiding hydrogen gas (H₂ gas) from the hydrogen gas supply source 15 into the chamber 1; an excitation unit. 17 for generating excited hydrogen by exciting H₂ gas supplied into the chamber 1. The excited hydrogen may be hydrogen ion, hydrogen radical or hydrogen plasma.

In the example shown in FIG. 1, the excitation unit 17 is configured as a filament which emits thermal electrons into the chamber 1 to dissociate H₂ gas into hydrogen ions (H⁺). However, the excitation unit 17 is not limited to the filament as long as the excited hydrogen can be generated in the chamber 1.

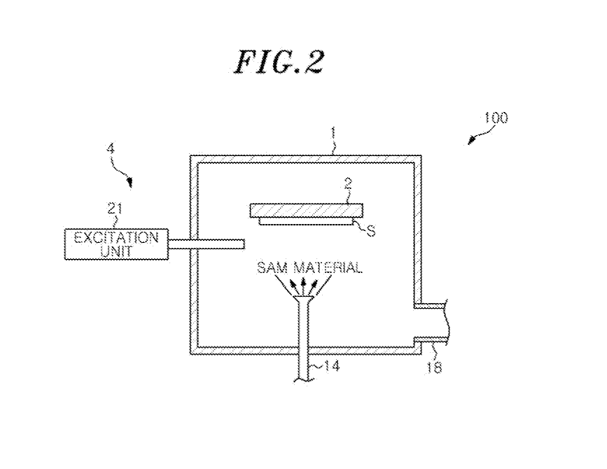

Alternatively, as shown in FIG. 2, the excited hydrogen generation mechanism 4 may have: an excitation unit 21, provided outside the chamber 1, for generating excited hydrogen by exciting H₂ gas; and an excited hydrogen introduction member 22 for introducing the excited hydrogen from the excitation unit 21 into the chamber 1. The excitation unit 21 may be a remote plasma source but is not limited thereto.

The gas exhaust system 5 includes: a gas exhaust line 18 connected to a lower portion of the chamber 1; a pressure control valve 19 provided at the gas exhaust line 18; and a vacuum pump 20 for exhausting the inside of the chamber 1 through the gas exhaust line 18.

The control unit 6 includes a controller having a microprocessor (computer) for controlling the respective components of the apparatus 100. The controller controls, e.g., a flow rate of a carrier gas from the carrier gas introduction line 13, an output of the excitation unit 17, a flow rate of H₂ gas, an opening degree of the pressure control valve 19 and the like. The controller is connected to a user interface. The user interface includes a keyboard used for an operator to input commands to manage the apparatus 100, a display for visually displaying an operation state of the apparatus 100, and the like. Further, the controller is connected to a storage unit that stores processing recipes and various databases and the like. The processing recipes include a control program for realizing a desired operation in a film forming process executed in the apparatus 100 under the control of the controller, and a control program for executing a predetermined process in respective components of the apparatus 100 depending on processing conditions. The processing recipes are stored in an appropriate storage medium in the storage unit. if necessary, any processing recipe is retrieved from the storage unit and executed by the controller. Accordingly, a desired process is performed in the apparatus 100 under the control of the controller.

(Organic Monolayer Forming Method)

Hereinafter, an organic monolayer forming method in accordance with an embodiment of the present invention will be described.

In the present embodiment, a SAM as an organic monolayer is formed on the substrate S.

A SAM material used in forming the SAM contains organic molecules each having a binding site that is to be chemically bonded to the surface of the substrate. Typically, it is possible to use a material (silane coupling agent) containing organic molecules expressed by a general formula R′—Si(O—R)₃. Here, R′ represents an alkyl group and OR represents a hydrolysable functional group, e.g., a methoxy group or an ethoxy group. O—R serves as a binding site. The silane coupling agent may be, e.g., octamethyl tremethoxy silane (OTS).

Conventionally, in the SAM formation using a silane coupling agent, a substrate having on a surface thereof SiO₂ is used and the following reactions (1) and (2) referred to as silane coupling are made to occur on the surface of the substrate.

R′—Si(O—R)₃+H₂O→R′—Si(OH)₃+ROH (1)

R′—Si(OH)₃+SiO(surface)→R′—SiO+Si(surface)+H₂O (2)

As a result of the reaction, a unimolecular alkyl group R′ is attracted to the SiO₂ surface and surface property is changed. The reaction (1) is a first step for hydrolysis of the SAM material and the reaction (2) is a second step for polycondensation with the substrate.

Conventionally, the SAM material adheres on the substrate by way of exposing the substrate to vapor of the SAM material, dipping the substrate in SAM material solution, or coating the substrate with SAM material solution. Thereafter, the substrate stays in the atmosphere to cause the reactions (1) and (2). In this manner, the SAM is formed.

Such a method is advantageous in that it is cost-effective because the reaction proceeds simply by adhering the material onto the substrate. However, the reactions (1) and (2) proceed for days at a considerably low speed and a long period of time is required to form a desired SAM. For this reason, problems such as low throughput, cross contamination and the like occur. Further, such a method is disadvantageous in that controllability in film formation is poor due to the use of moisture in the atmosphere. As a consequence, it is difficult to form a high-density film on the substrate and the film thus formed may be easily peeled off, Moreover, in the above reactions, the surface of the substrate is restricted to a silicon oxide film.

In the conventional reaction (1), R′—Si(OH)₃ is generated from R′—Si (O—R)₃ by using water in the air. This is a substitution reaction of the alkyl group R at the end of the binding site with hydrogen. Actually, the reaction of generating desired R′—Si(OH)₃ by substituting the alkyl group with hydrogen requires only hydrogen. Since water is used in the reaction (1), water is decomposed into hydrogen and a hydroxyl group. The hydroxyl group may suppress the substitution reaction between alkyl group and hydrogen. This is because the hydrogen is positively charged as H⁺ and the hydroxyl group is negatively charged as OH⁻.

Therefore, in the present embodiment, the substitution reaction of the alkyl group at the end of the binding site with hydrogen is completed without using water before the SAM material reaches the substrate. To do so, in the present embodiment, highly reactive excited hydrogen (hydrogen radical, hydrogen ion, hydrogen plasma) is mixed with the SAM material.

Specifically, in the apparatus 100 shown in FIG. 1, in a state where the substrate S is held by the substrate holder 2 in the chamber 1, the SAM material gas obtained by vaporizing the liquid SAM material L in the SAM material accommodating container 12 is transferred by the carrier gas and supplied into the chamber 1 through the SAM material gas supply line 14. Further, excited hydrogen is generated in the chamber 1 by the excited hydrogen generation mechanism 4 and mixed with the SAM material gas.

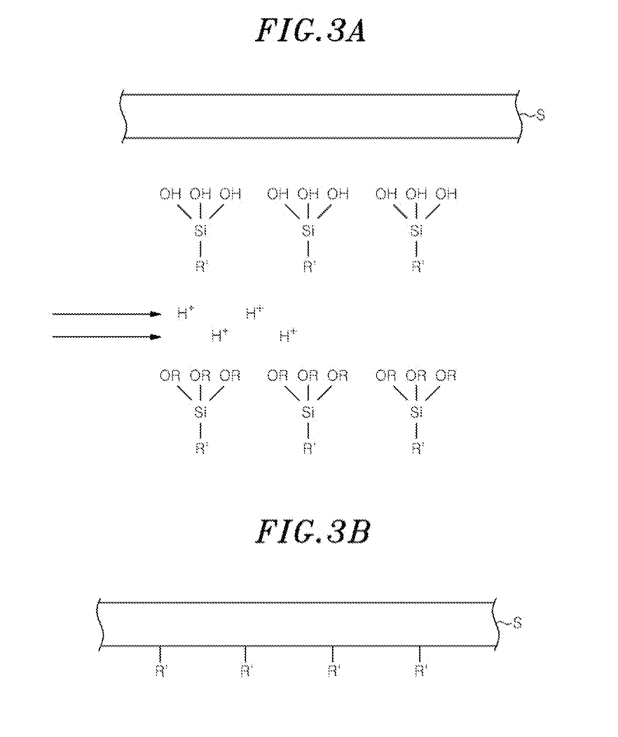

Accordingly, the following reaction (3) occurs, for example. Hence, as shown in FIG. 3A, highly reactive organic molecules each having ends respectively bonded with

OH groups are formed in the chamber 1 before the SAM material gas reaches the substrate S.

R′—Si(O—R)₃+H⁺→R′—Si(OH)₃+RH (3)

Therefore, the highly reactive organic molecules each having hydrogens substituted for alkyl groups at the ends of a binding site reach the substrate S and at this time the reaction (2) is rapidly completed. As a consequence, as shown in FIG. 35, a unimolecular alkyl group R′ is adhered onto the substrate S, thereby forming a monolayer.

By using the SAM material, the reaction can rapidly occur on the substrate as in the case of dry film formation such as CVD (chemical vapor deposition), PVD (physical vapor deposition) or the like. Therefore, the reaction time can be considerably reduced compared to the conventional case and a high throughput can be obtained as in the case of performing CVD or PVD. Since the reaction time is reduced, cross contamination hardly occurs. Further, the reactivity can be controlled by controlling the amount of hydrogen, a pressure in the chamber 1, a temperature of the substrate S or the like. Accordingly, by controlling the reactivity of the SAM material, a film can be formed with high controllability as in the case of performing CVD or PVD. Hence, a high-density film can be formed and the film thus formed is not easily peeled off. Since the organic molecules terminated with the hydroxyl group reach the substrate, the surface of the substrate can also be made of, e.g., nitride such as SiN, without being limited to SiO₂. Further, since the alkyl group at the end of the binding site is substituted with hydrogen without using water, the hydroxyl group due to decomposition of water is not produced and the reaction does not suppressed.

When the surface of the substrate is made of SiN, the following reaction (4) occurs instead of the reaction (2), thereby generating ammonia (NH₃).

R′—Si(OH)₃+Sin(surface)→R′—SiN+Si(surface)+NH₃ (4)

In the present embodiment, the organic monolayer is formed under, e.g., the following conditions: a pressure in the chamber during vacuum suction is the order of 10⁻⁵ Pa; a hydrogen partial pressure is the order of 10⁻³ Pa; and a substrate temperature ranges from a room temperature to 200° C.

The organic monolayer thus formed can be used for an organic thin film for an organic semiconductor, modification of a substance surface, a photoresist or the like.

(Other Applications)

The present invention may be variously modified without being limited to the above embodiment. For example, in the above embodiment, a silane coupling agent has been used a SAM material for forming an organic monolayer, but the SAM material is not limited thereto.

Further, as for a SAM material gas, an organic material gas evaporated from a liquid has been supplied by a carrier gas in the above embodiment, but the present invention is not limited thereto and the SAM. material gas may be generated by using bubbling, a vaporizer or the like.

Furthermore, an organic monolayer has been formed on a substrate in the above embodiment, but, an object. on which the organic monolayer is formed is not limited to the substrate. For example, in the case of applying the present invention to a container-shaped object, a container having a modified surface can be manufactured.

While the invention has been shown and described with respect to the embodiments, it will be understood by those skilled in the art that various changes and modifications may be made without departing from the scope of the invention as defined in the following claims.

What is claimed is:

1. A method for forming an organic monolayer, comprising:
supplying to an object an organic material gas including organic molecules, each molecule having a binding site that is to be chemically bonded to a surface of the object;
supplying excited hydrogen to the organic material gas before the organic material gas reaches the object to substitute an end of the binding site with hydrogen; and
forming an organic monolayer by reaction between the end substituted with the hydrogen and the object.

2. The method of claim 1, wherein the organic monolayer includes a self-assembled monolayer.

3. The method of claim 2, wherein the organic material gas includes a silane coupling agent.

4. The method of claim 1, wherein an alkyl group is at the end of the binding site of the organic material gas, and the alkyl group is substituted with the hydrogen by the excited hydrogen.

5. The method of claim 1, wherein the excited hydrogen is at least one of hydrogen ion, hydrogen radical and hydrogen Plasma.

6. An apparatus for forming an organic monolayer on a surface of an object, the apparatus comprising:
a chamber configured to accommodate the object;
an organic material gas supply unit configured to supply into the chamber an organic material gas including organic molecules, each molecule having a binding site that is to be chemically bonded to the surface of the object;
an excited hydrogen generation mechanism configured to generate excited hydrogen in the chamber; and
a gas exhaust unit configured to exhaust an inside of the chamber; and
a control unit configured to supply the excited hydrogen from the excited hydrogen generation mechanism to the organic material gas supplied from the organic material gas supply unit before the organic material gas reaches the object in the chamber, so that an end of the binding site of each organic molecule is substituted with hydrogen and an organic monolayer is formed by reaction between the end substituted with the hydrogen and the object.

7. The apparatus of claim 6, wherein the excited hydrogen generation mechanism includes:
a hydrogen gas supply unit for supplying hydrogen gas into the chamber; and
an excitation unit for exciting the hydrogen gas in the chamber.

8. The apparatus of claim 6, wherein the excited hydrogen generation mechanism includes:
an excitation unit for generating the excited hydrogen outside the chamber; and
an excited hydrogen introduction member for introducing the excited hydrogen generated by the excitation unit into the chamber.

9. The apparatus of claim 6, wherein the organic monolayer includes a self-assembled monolayer.

10. The apparatus of claim 9, wherein the organic material gas includes a silane coupling agent.

11. The apparatus of claim 6, wherein an alkyl group is at the end of the binding site of the organic material gas and the alkyl group is substituted with the hydrogen by the excited hydrogen.

12. The apparatus of claim 6, wherein the excited hydrogen is at least one of hydrogen ion, hydrogen radical and hydrogen plasma.
